(19) United States
(12) Patent Application Publication
(10) Pub. No.: US 2007/0182597 A1
(43) Pub. Date: Aug. 9, 2007

(54) Modulation code system and methods of encoding and decoding a signal

(75) Inventors: Hendrik Dirk Lodewijk Hollmann, Eindhoven (NL); Johannes Wilhelmus Maria Bergmans, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 10/599,614

(22) PCT Filed: Apr. 1, 2005
(86) PCT No.: PCT/IB05/51093

§ 371 Date: Oct. 3, 2006

(30) Foreign Application Priority Data
Apr. 9, 2004 (EP) 04101472.1

(51) Int. Cl. H03M 7/00

(52) U.S. Cl. 341/50

(57) ABSTRACT

The invention relates to a modulation code system and methods of encoding and decoding a signal to be used for data transmission or data storage. Such systems comprise an encoder (100) for transforming an original signal s into an encoded signal c satisfying predefined second constraints before said signal being transmitted via a channel (300). Such modulation code systems further comprise a decoder (200) for decoding the encoded signal c, after restoration, back into the original signal s. It is the object of the invention to improve such known systems and methods in such a way that they require less hardware. This object is achieved according to the invention in that the encoder (100) comprises a modulation encoder (110) transforming the original signal s into an intermediate signal t satisfying predefined first constraints and a transformer encoder (120) for transforming the intermediate signal t into the encoded signal c. The object is further achieved in such a way that the decoder (200) comprises a transformer decoder (220) for re-transforming the encoded signal c into said intermediate signal t and a modulation code decoder (210) for decoding that intermediate signal t into said original signal s.

The invention relates to a modulation code system as shown in FIG. 4, including an encoder 100 for transforming an original signal s into an encoded signal c satisfying predefined second constraints before said signal being transmitted via a channel 300 or stored on a recording medium (not shown). This modulation code system further comprises a decoder 200 for decoding the encoded signal c, after restoration or receipt, back into the original signal s. The invention further relates to a decoder, encoder. Furthermore the invention relates to a method of encoding and decoding.

Such a modulated code system known in the art is used predominantly in data transmission systems or data storage systems.

The invention further relates to known methods of operating the encoder 100 and the decoder 200.

In the following, reference is made to different signals satisfying different constraints. The constraints are typically either simple or complicated. A signal satisfying simple constraints is e.g. a (0,k)-constrained signal, which is a binary signal where the number of consecutive zeros is at most k+1. A signal satisfying complicated constraints, however, is a signal satisfying run length constraints on more complicated patterns, like e.g. the transition patterns of the anti-whistle patterns as listed in Table 1.

Traditionally, encoders or decoders of modulation code systems use specific modulation methods, e.g. the enumerative encoding method or the integrated scrambling method. The enumerative encoding method is e.g. known from K.A.S. Immink, “A practical method for approaching the channel capacity of constrained channels”, IEEE Trans. Inform. Theory, vol. IT-43, no. 5, pp. 1389-1399, September. 1997. The integrated scrambling method is e.g. known from K.A.S. Immink, “Codes for mass data storage systems”, Shannon Foundation Publishers, The Netherlands, 1999.

Modulation codes such as (d,k)-codes and (d,k)-RLL codes are widely employed in digital transmission and storage systems. A modulation code consists of an encoder which serves to transform arbitrary sequences of source bits into sequences that satisfy certain constraints and a decoder to recover the original source from the constrained sequence. A binary sequence is said to be (d,k)-constrained if any two consecutive ones in the sequence are separated by at least d and at most k zeroes; it is said to be (d,k)-RLL constrained if the minimum and maximum run lengths are at least d+1 and at most k+1, respectively. The use of constrained sequences enables the data receiver to extract control information to be used for, for example, timing recovery, gain control, or equalisation adaptation.

Many modem data receivers employ adaptive equalization or bandwidth control. In some CD or DVD systems two-dimensional adaptive equalization is used to combat not only inter-symbol interference along the track but also inter-track interference (cross-talk cancellation). Also, in certain data receivers the only adaptive part is a circuit for slope control. In order for such systems to function properly, the frequency components of the received signal must obey certain constraints which in turn dictate(s ?) the use of data sequences in which the maximum (run)length of certain (periodic) data patterns is limited. As a typical example are mentioned constraints on data patterns of period 1 or 2 (k₁- and k₂-constraints) that are already used in practical systems. Periodic data patterns with a specific length will result in a whistle with a respective frequency. A known problem in receiving systems is that whistles in a received signal have a negative influence on the functioning of for example the PLLs in the receiver or gain control and thus on the reconstruction of the transmitted data. Therefore, there is a need to generate data sequences that do not generate sequences that could negatively influence the reconstruction of the transmitted data .

Hereafter some definitions are given to improve the understanding of the technical field.

A sequence is (k;p)-pattern-constrained if it does not contain a run of length k of the pattern p. What is given is a pattern p=(p₀p₁..P₋₁ Pₑ) which is interpreted as representing the periodic sequence . . . ,p₀,p₁, . . . ,pₑ₋,pₑ,p₀, . . . ,pₑ₋₁, . . . of period e. A sequence is (k;P)-pattern constrained if the sequence is (kᵢp⁽ⁱ⁾-constrained for all i, wherein k=k₁, . . . , kᵢ, which is a sequence of positive integers k, and P=,p⁽¹⁾, . . . p⁽ⁱ⁾, which is a sequence of periodic patterns. A sequence is P-pattern-constrained if it is (k;P)-pattern constrained for some k.

A k-constrained sequence is a binary sequence where the number of consecutive zeroes is at most k. These sequences are precisely the (k;p)-constrained sequences for the pattern p=(0).

A k-RLL-constrained sequence is a sequence with symbols from {−1,1}, thus a binary sequence, where the maximum run of each of the symbols is at most k+1. These sequences are precisely the (k;P)-pattern constrained sequences with k=k+1 and P=(−1), (1).

An anti-whistle constrained sequence is a pattern that has only a single frequency component in the pass band ranging from dc to the Nyquist frequency. Table 1 discloses some anti-whistle patterns and the corresponding index. Anti-whistle transition patterns are obtained by one time integrating/differentiating the anti-whistle pattern.

TABLE 1
Anti-whistle transition patterns.

| | | | | period |
|---|---|---|---|---|
| | | period | anti-whistle | anti-whistle |
| | anti-whistle | anti-whistle | transition | transition |
| index | pattern | pattern | pattern | pattern |
| 1 | 0 | 1 | 0 | 1 |
| 2 | 01 | 2 | 1 | 1 |
| 4^{a} | 0011 | 4 | 01 | 2 |
| 4^{b} | 0111 | 4 | 0011 | 4 |
| 3 | 011 | 3 | 011 | 3 |
| 6 | 000111 | 6 | 001 | 3 |

These known methods of encoding/decoding enable the transformation of the original signal s into the signal c satisfying second constraints and back again, usually at a modulation code rate close to 1. The rate of a modulation code is a number that refers to the average number of encoded signals per source symbol: For example, an encoder of rate 1/2 code produces (on average) two encoded symbols for each source symbol.

At least the decoder of such known modulation code systems is usually implemented in hardware for enabling high-speed operation. However, hardware implementation of the above mentioned modulation code methods disadvantageously requires quite a lot of hardware, e.g. to store necessary tables. In the known modulation coders the relation between input words and corresponding output words is uniquely defined.

The invention relates to a modulation code system as shown in FIG. 4, including an encoder 100 for transforming an original signal s into an encoded signal c satisfying predefined second constraints before said signal is transmitted via a channel 300 or stored on a recording medium. This modulation code system further comprises a decoder 200 for decoding the encoded signal c, after restoration or receipt, back into the original signal s.

Such a modulated code system known in the art is used predominantly in data transmission systems or data storage systems.

Based on that prior art it is the object of the invention to improve a known modulation code system and known methods of operating an encoder and a decoder of said modulation code system such that they require less hardware.

This object is achieved by the subject matters of apparatus claims 1, 2 and 9.

More specifically, this object is achieved by an encoder comprising a modulation code encoder for transforming the original signal s into an intermediate signal t satisfying said predefined first constraints and a transformer encoder for transforming the intermediate signal t into the encoded signal c.

The first constraints may in general be simpler, equally complicated or more complicated than the second constraints. However, in typical applications the first constraints are simpler than the second constraints.

The object is further achieved by a decoder comprising a transformer decoder for re-transforming the encoded signal c into said intermediate signal t and a modulation code decoder for decoding the intermediate signal t into said original signal s.

The modulation code encoder and the modulation code decoder according to the invention do not need to fulfill any specific requirements and thus any suitable encoder or decoder may be used.

However, by designing the encoder as a series connection of a modulation code encoder with a transformer encoder and by designing the decoder as a series connection of the transformer decoder with the modulation code decoder, the required hardware in both the encoder and decoder is advantageously substantially reduced.

An advantageous example of a simple transformer encoder design is given in claim 6 and an advantageous embodiment of a simple transformer decoder design is given in claim 11.

Further advantageous embodiments of a modulation code system, of the encoder or of the decoder, are subject matters of the dependent claims. The term rate −1 transformer refers to a transformer having a modulation code rate equal to 1, such as a 99 to 100 coder.

The above-identified object of the present invention is further achieved by an encoding method and a decoding method according to claims 8 and 16. The advantages of these methods correspond to the advantages of the encoder and the decoder as discussed above.

An advantageous embodiment of the decoding method is given in claim 16.

The description is accompanied by four Figures, wherein

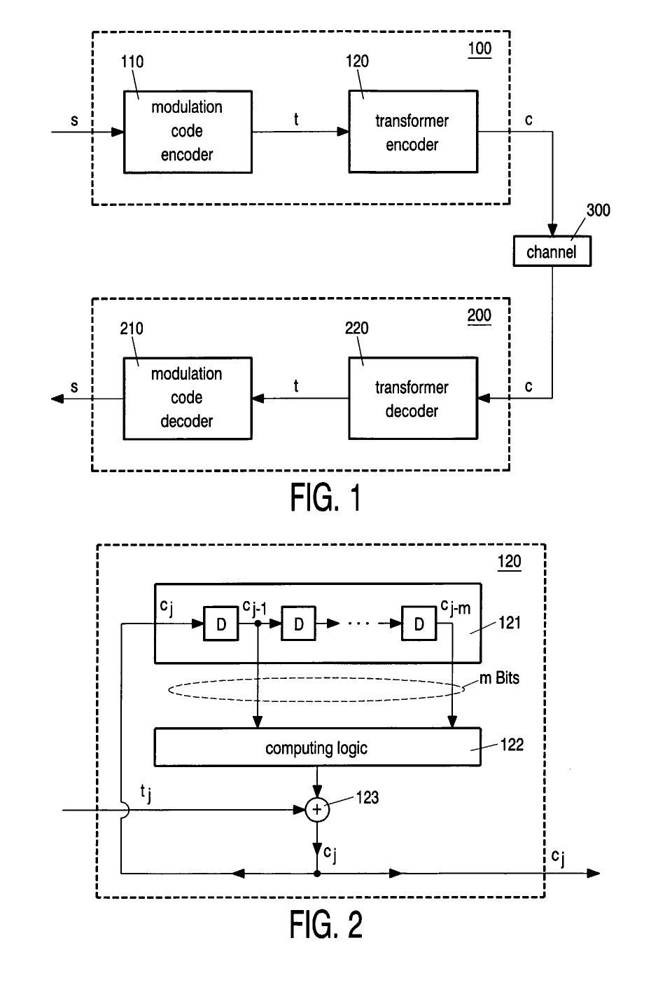

FIG. 1 shows the modulation code system according to the invention;

FIG. 2 shows an embodiment of the transformer encoder according to the present invention;

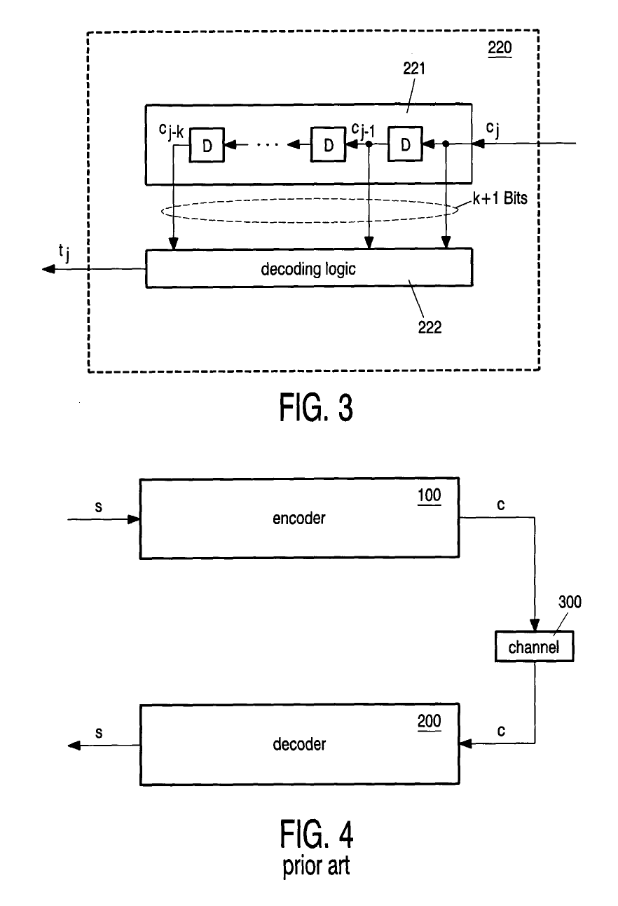

FIG. 3 shows an embodiment of the transformer decoder according to the present invention; and

FIG. 4 shows a modulation code system known in the art.

Several embodiments of the invention will be discussed by referring to FIGS. 1-3.

FIG. 1 shows a preferred embodiment of the modulation code system according to the present invention. It comprises an encoder 100, preferably having a modulation code rate close to or equal to 1. The encoder 100 comprises a modulation code encoder 110 for transforming an original signal s into an intermediate signal t satisfying predefined first constraints. The first constraints may e.g. be simple constraints; in that case the signal is for example the (0,k)-constrained signal as explained above. The intermediate signal t might be latched in a first memory (not shown).

The encoder 100 further comprises a transformer encoder 120 being connected in series behind that modulation code encoder 110 for transforming the intermediate signal t into an encoded signal c. The encoded signal c is subsequently e.g. transmitted via a channel 300 or stored on a recording medium (not shown). The recording medium can be any kind of storage medium such as optical record carrier (CD, DVD) or Hard Disk Drive

After transmission via said channel 300 or after restoration from said recording medium the encoded signal c is decoded in a decoder 200 in order to restore the original signal s. For achieving this restoration the decoder 200 comprises a transformer decoder 220 for re-transforming the encoded signal c into that intermediate signal t. The intermediate signal in the decoder might be latched by a second memory (not shown). The decoder 200 further comprises a modulation code decoder 210 which is connected in series behind that transformer decoder 200 for receiving said intermediate signal t output from said transformer decoder 220 and for decoding the intermediate signal t into an original signal s.

In the following detailed description of the transformer encoder according to FIG. 2 and of the transformer decoder according to FIG. 3, the signals s, t and c are assumed to be sequences of bits sⱼ, tⱼ and cⱼ, respectively, wherein the parameter j represents the clock of the signal or sequence.

FIG. 2 shows a preferred embodiment of the transformer encoder 120. The transformer encoder comprises a shift-register 121 defining a window for selecting and outputting a predetermined number of m+p1 bits cⱼ−cⱼ₋m from the serial encoded signal c. For defining said window the shift register 121 comprises a series connection of m delay elements D the outputs of which represent the bits cⱼ₋₁−cⱼ₋ₘ, respectively. The bit cⱼ of the signal c is input into the first of said delay elements D in said series connection and also output from the shift register 121. The transformer encoder 120 further comprises a computing logic 122 for receiving in parallel the m+1 bit-sequence cⱼ−cⱼ₋ₘ output by said shift-register 121 and for logically combining said sequence into a logical output value. The logical combination is done according to a predefined mathematical function F(cⱼ₋₁, . . . , cⱼ₋ₘ). The transformer encoder 120 further comprises a logical XOR-Gate 123 for XOR combining a received bit tⱼ of the intermediate signal t with said logical output value output by said computing logic 122 in order to generate said bit cⱼ of said encoding signal c. The transformer encoder 120 can be implemented in hardware as well as software.

FIG. 3 shows a preferred embodiment of the transformer decoder 220. The transformer decoder comprises a shift-register 221 for defining a window for selecting a predetermined number of k+1 bits cⱼ−cⱼ₋ₖ from the received restored serial encoded signal c and for outputting said selected k+1 bits cⱼ−cⱼ₋ₖ in parallel to a decoding logic 222 which is also part of that transformer decoder 220. For defining said window, the shift register 221 comprises a series connection of m delay elements D the outputs of which represent the bits cⱼ₋ₗ−cⱼ₋ₖ, respectively. The bit cⱼ of the signal c is input into the first of said delay elements D in said series connection and also output from the shift register 121. The decoding logic 222 serves for receiving and logically combining said k+1 parallel bits output from said shift-register 221 in order to restore the bits tⱼ of that intermediate signal t. Said transformer decoder 220 is preferably implemented in hardware in order to enable high-speed operation. Due to the specific hardware design shown in FIG. 3, the transformer decoder 220 is also referred to as sliding block decoder. The transformer decoder 220 carries out the inverse operation of said transformer encoder 120.

It will be pointed out once again that the effort required for designing the encoder 100 and the decoder 200 according to the invention, is far less than the effort required for modifying the modulation code methods known in the art to comply with the new second constraints.

In the following a mathematical discussion is provided on the design of the transformer encoder followed by the description of a practical example. More specifically, the following considerations are made for any rate-i finite-state transformer encoder 120, which is sliding block decodable. The discussion is limited to the case where the sliding block decoder is based on a simple block map so that invertibility problems need not be considered.

Let P be a collection of patterns. Here a pattern is a sequence p=(p₀. . . pₑ₋₁) that stands for a periodic signal of period e. We say that a signal c satisfies a (k,p)-pattern constraint if c has at most k consecutive symbols in common with p, that is, for no integer n and no d from 0, . . . , e−1, it is true that Cₙ₊ⱼ=P_{d+j} for j=0, . . . , k. (Here indices on p are to be considered modulo e.)

More generally, a signal c is said to be P-pattern constrained if for each p from P the signal c is (k,p)- constrained for some k.

More specifically, in the following the problem of designing a complicated P-pattern constrained modulation code from a given simple k-constrained code is considered. In order to achieve this, a simple block map φ needs to be constructed that annihilates (maps to 0) each of the patterns from P. A block map is a map φ:F^{w}→E that maps w-tuples of symbols from some fixed finite alphabet F to symbols from a second alphabet E. Such a block map φ defines a map from sequences x over F to sequences y over E by letting Xₙ=φ(y_{n-w+1}, . . . , yₙ). A block map φ:F^{w} →E is called simple if for all a=(a₁, . . . , a_{w-1}) over F the map fₐ : F−>E defined by fₐ(x)=φ(a₁, . . . , a_{w-1}, x) is onto, that is, for each y in E there exists x in F such that fₐ(x)=y. It is true that a simple block map is always invertible. In what follows all symbols are assumed to be binary. Supposing that the window of the sliding block encoder has the size m+1, then for each pattern p=(p₀. . . pₑ₋₁,) from P and for each d, a window content w₀. . . wₘ, where Wᵢ=p_{i+d mod e}, should be mapped to 0. Since the block map must be simple, it is required that two window contents w=w₀..wₘ₋₁,wₘ and w′=w₀. . . wₘ₋₁, wₘ′ with wₘ≠wₘ′ are mapped to distinct bits. If these two requirements are satisfied, then the concatenated code will obey a (k+m,p)-pattern constraint for each of the patterns p. In order to obtain pattern-constraints of varying severity, in addition only a suffix of the window content must force the window content to be mapped to 0. So to design the block map, the collection of suffixes W, for which each window content with a suffix contained in W is mapped to 0, must be specified. In view of the above, the collection W should have the following properties,
The collection W does not contain two words w=w_{d}. . . w₀ and w′=wₑ′. . . w₀′ for which wⱼ=wⱼ′ for j=0, . . . , min(d,e).
For each pattern p=(p₀. . . pₑ₋₁,) from P and for each d with 0≦d<e the left-infinite word
   p[d]:=. . . P₀. . . pₑ₋₁p₀. . . pₑ₋₁P₀. . . P_{d}
   has a suffix contained in W.

Then, if m is the maximum length of words from W, the block map φ with window size m is partly specified by requiring that φ(x₀. . . xₘ₋₁)=0 whenever the word x=x₀. . . . xₘ₋₁ has a suffix in W. The first condition ensures that both the collection W is minimal (no word in W is suffix of another word in W) and that the partly specified block map can be extended to a simple block map; the second condition ensures that each run of length k+m+1 of a pattern p from P is mapped by the sliding block decoder to a run of zeroes of length at least k+1.

To build the minimal suffix list W(P) for a given collection P of patterns, the process is proceeded as follows. For each pattern p=p₀. . . pₑ₋₁ from P and for each shift d, where 0≦d<e, the left-infinite word p[d] is considered. It is assumed that the w′(p,d) is the shortest suffix of p[d] that is not also a suffix of another left-infinite word of this type. Then the word w(p,d) :=w′(p,d)p_{d} is included in the suffix list W(P). It is not difficult to see that the resulting suffix list W(P) is minimal, in the sense that if W is another valid suffix list for P, then each window contents that is forced to be mapped to 0 by the collection W is also forced to map to 0 by collection W(P).

In the following, the above consideration will be illustrated by an example.

In that example the design of a pattern-constrained code for the transition patterns of the anti-whistle patterns as listed in Table 1 above shall be considered. For each of these patterns Table 2 lists the sequence p[d], the minimal suffix w(p,d), a next bit and the resulting suffix w(p,d) to be included in the list W(P).

It is assumed that W denotes the collection of all words in the last column of Table 2, and it is further assumed that W^{*} denotes the collection of all words w₀,.., wᵣ₋₂, w“ᵣ₋₁ for which the word w₀, . . . , Wᵣ₋₂, wᵣ₋₁ is in W. (Given a binary symbol x, the complementary symbol 1−x is denoted by x“.)

TABLE 2
Anti-whistle transition patterns and suffixes.

| sequences p[d] | minimal suffix | next bit | Resulting suffix |
|---|---|---|---|
| . . . 0 | 000 | 0 | 0000 |
| . . . 1 | 111 | 1 | 1111 |
| . . . 01 | 0101 | 0 | 01010 |
| . . . 10 | 1010 | 1 | 10101 |
| . . . 0011 | 0011 | 0 | 00110 |
| . . . 1001 | 11001 | 1 | 110011 |
| . . . 1100 | 1100 | 1 | 11001 |
| . . . 0110 | 00110 | 0 | 001100 |
| . . . 100 | 0100 | 1 | 01001 |
| . . . 010 | 0010 | 0 | 00100 |
| . . . 001 | 01001 | 0 | 010010 |
| . . . 011 | 1011 | 0 | 10110 |
| . . . 101 | 1101 | 1 | 11011 |
| . . . 110 | 10110 | 1 | 101101 |

Note that this construction ensures that W and W^{*} are disjoint. If φ:{0,1}⁶ →{0,1} is designed such that φ maps any 6-bit word with a suffix contained in W and any 6-bit word with a suffix contained in W^{*} to 1, then φ can be extended to a simple block map; moreover, each such extension produces a rate-1 finite-state encodable sliding block decodable code which, when concatenated with a k-constrained code, produces a pattern-constrained code where the run of the various anti-whistle transition patterns p is limited to the values kₚ as listed in Table 3.

TABLE 3
Maximum run lengths of anti-whistle transition patterns

| anti-whistle pattern p | kₚ |
|---|---|
| (0) | K + 3 |
| (1) | k + 3 |
| (01) | k + 4 |
| (1100) | k + 5 |
| (011) | k + 5 |
| (100) | k + 5 |

Though the invention is described with reference to preferred embodiments thereof, it is to be understood that these are non-limitative examples. Thus, various modifications are conceivable to those skilled in the art, without departing from the scope of the invention, as defined by the claims.

The use of the verb “to comprise” and its conjugations does not exclude the presence of elements or steps other than those stated in a claim. Furthermore, the use of the article “a” or “an” preceding an element does not exclude the presence of a plurality of such elements. In the claims, any reference signs placed between parentheses shall not be construed as limiting the scope of the claims. The invention may be implemented by means of hardware as well as software. The same item of hardware may represent several “means”. Furthermore, the invention resides in each and every novel feature or combination of features.

1. Modulation Code system comprising
an encoder (100) for transforming an original signal s into an encoded signal c satisfying predefined second constraints before the signal being transmitted via a channel (300) or stored on a recording medium; and
a decoder (200) for decoding the encoded signal c, after restoration, back into the original signal s; wherein
the encoder (100) comprises a modulation code encoder (110) for transforming the original signal s into an intermediate signal t satisfying predefined first constraints and a transformer encoder (120) for transforming the intermediate signal t into the encoded signal c; and
the decoder (200) comprises a transformer decoder (220) for re-transforming the encoded signal c into said intermediate signal t and a modulation code decoder (210) for decoding said intermediate signal t into said original signal s.

2. An encoder (100) as part of the system as claimed in claim 1, comprising
the modulation code encoder (110) for transforming the original signal s into the intermediate signal t satisfying said predefined first constraints and
the transformer encoder (120) for transforming the intermediate signal t into the encoded signal c.

3. The encoder (100) according to claim 2, wherein the modulation code encoder (110) is an (0,k)-encoder.

4. The encoder (100) according to claim 2, wherein the encoder has a modulation code rate close to 1.

5. The encoder (100) according to claim 4, wherein the transformer encoder (120) has a modulation code rate close to or equal to 1.

6. The encoder (100) according to claim 2, wherein the transformer encoder (120) comprises
a shift-register (121) for defining a window for selecting a predetermined number of m+1 bits cⱼ−cⱼ₋ₘ from the serial encoded signal c and for outputting said selected m+1 bits cⱼ−cⱼ₋ₘ in parallel;
a computing logic (122) for logically combining the received parallel (m+1) -bits cⱼ−cⱼ₋ₘ output by said shift-register (121) into a logical output value; and
a logical XOR-Gate (123) for XOR combining the bits tj of the received intermediate signal t with said logical output value in order to generate the bits cⱼ of said encoded signal c.

7. The encoder (100) according to claim 2, wherein the transformer encoder (120) is implemented in software or hardware.

8. Encoding method for transforming an original signal s into an encoded signal c satisfying predefined second constraints;
characterized by the following steps:
transforming the original signal s into an intermediate signal t satisfying predefined first constraints; and
transforming the intermediate signal t into the encoded signal c satisfying said second constraints.

9. A decoder (200) as part of the system as claimed in claim 1, characterized by the transformer decoder (220) for re-transforming the encoded signal c into said intermediate signal t; and the modulation code decoder (210) for decoding said intermediate signal t into said original signal c.

10. The decoder (200) according to claim 9, wherein the transformer decoder (220) is a sliding block decoder.

11. The decoder (200) according to claim 9, wherein the transformer decoder (220) comprises
a shift-register (221) for defining a window for selecting a predetermined number of k+1 bits cⱼ−cⱼ₋ₖ from the received restored serial encoded signal c and for outputting said selected k+1 bits cⱼ−cⱼ₋ₖ in parallel; and
a decoding logic (222) for receiving and logically combining said parallel bits cⱼ−cⱼ₋ₖ from said restored encoded signal c in order to restore bits tj of said intermediate signal t.

12. The decoder (200) according to claim 9, wherein the modulation code decoder (220) is a (0,k)-decoder.

13. The decoder (200) according to claim 9, wherein the decoder (200) has a modulation code rate close to 1.

14. The decoder (200) according to claim 13, wherein the transformer decoder (220) has a modulation code rate close to or equal to 1.

15. The decoder (200) according to claim 9, wherein the transformer decoder (220) is implemented in hardware or software.

16. Decoding method for decoding a restored encoded signal c satisfying predetermined second constraints into an original signal s characterized by the following steps:
re-transforming the restored encoded signal c into an intermediate signal t satisfying predetermined first constraints; and
decoding the intermediate signal t into the original signal s.

17. The decoding method according to claim 16, wherein the step of re-transforming the encoded signal comprises the steps of:
a) determining the number k of consecutive bits cⱼ which must be considered in the restored encoded signal c in order to detect all specific patterns which are forbidden in the encoded signal according to said second constraints;
b) defining the window seize to k+1; and
c) determining a logic such that it transforms the k+1 bits cⱼ−cⱼ₋ₘ of the encoded signal c in the window—in the case that these k+1 bits cⱼ−cⱼ₋ₘ represent a forbidden pattern—into a bit value which corresponds to the value of the bit at the position k+2 of the encoded signal c.
